(19) United States
(12) Patent Application Publication
(10) Pub. No.: US 2024/0347415 A1
(43) Pub. Date: Oct. 17, 2024

(54) HEAT DISSIPATION MEMBER AND ELECTRONIC DEVICE

(71) Applicant: DENKA COMPANY LIMITED, Chuo-ku, Tokyo (JP)

(72) Inventors: Motoi NAGASAWA, Tokyo (JP); Hyojin NOGUCHI, Tokyo (JP)

(73) Assignee: DENKA COMPANY LIMITED, Chuo-ku, Tokyo (JP)

(21) Appl. No.: 18/681,594

(22) PCT Filed: Jul. 27, 2022
(86) PCT No.: PCT/JP2022/028969

§ 371 Date: Feb. 6, 2024

(30) Foreign Application Priority Data
Aug. 6, 2021 (JP) 2021-129884

(51) Int. Cl. H01L 23/373; H01L 23/367

(52) U.S. Cl. CPC H01L 23/3732; H01L 23/367

(57) ABSTRACT

A heat dissipation member according to the present invention includes: a copper-diamond composite where a plurality of diamond particles are dispersed in a metal matrix containing copper; and a metal film that is joined to at least one face of the copper-diamond composite, in which in at least one cross-section of the heat dissipation member in a lamination direction, at least one of the plurality of diamond particles is configured to be in contact with both of the metal film and the metal matrix, and in a surface of the copper-diamond composite, a proportion of an exposed area of the diamond particles is 1% or more and 50% or less.

### TECHNICAL FIELD

The present invention relates to a heat dissipation member and an electronic device.

### BACKGROUND ART

Various heat dissipation members formed of a copper-diamond composite have been developed thus far. As this kind of technique, for example, a techniques described in Patent Document 1 is known. Regarding a composite material of a metal matrix and thermally conductive particles, Patent Document 1 describes that, since this composite material contains ceramic particles such as diamond particles or SiC particles, it is difficult to polish a surface of the composite material to be flat (paragraph 0012).

### RELATED DOCUMENT

### Patent Document

[Patent Document 1] Pamphlet of International Publication No. WO2016/035796

### SUMMARY OF THE INVENTION

### Technical Problem

However, as a result of investigation by the present inventors, it was found that the heat dissipation member described in Patent Document 1 has room for improvement of thermal conductivity.

### Solution to Problem

As a result of further investigation, the present inventors found that the thermal conductivity of the heat dissipation member can be improved by configuring the heat dissipation member to contain at least one diamond particle in contact with both of a metal film and a metal matrix and adjusting an exposed area of the diamond particles to be a predetermined value or less, thereby completing the present invention.

According to one aspect of the present invention, a heat dissipation member and an electronic device described below are provided.

1. A heat dissipation member including:
a copper-diamond composite where a plurality of diamond particles are dispersed in a metal matrix containing copper; and
a metal film that is joined to at least one face of the copper-diamond composite, in which
in at least one cross-section of the heat dissipation member in a lamination direction, at least one of the plurality of diamond particles is configured to be in contact with both of the metal film and the metal matrix, and
in a surface of the copper-diamond composite, a proportion of an exposed area of the diamond particles obtained from (the exposed area of the diamond particles/an area of the metal matrix)×100% is 1% or more and 50% or less.

2. The heat dissipation member according to 1, in which
the plurality of diamond particles include not only first diamond particles that are in contact with both of the metal film and the metal matrix but also second diamond particles of which all faces are embedded in the metal matrix, and
at least one of the first diamond particles and at least one of the second diamond particles are configured to be in contact with each other.

3. The heat dissipation member according to 1 or 2, in which a thermal conductivity of the copper-diamond composite is 600 W/m·K or higher.

4. The heat dissipation member according to any one of 1 to 3, in which
when a particle size distribution of the diamond particles is measured using an image particle size distribution analyzer, a sphericity S₅₀ corresponding to a cumulative value of 50% in a volume particle size distribution of sphericity of the diamond particles is 0.75 or more.

5. The heat dissipation member according to any one of 1 to 4, in which
when a particle size distribution of the diamond particles is measured using an image particle size distribution analyzer, a particle diameter D₅₀ corresponding to a cumulative value of 50% in a volume particle size distribution of particle diameter of the diamond particles is 300 μm or less.

6. An electronic device including:
the heat dissipation member according to any one of 1 to 5; and
an electronic component that is provided over the heat dissipation member.

### Advantageous Effects of Invention

According to the present invention, a heat dissipation member having an excellent thermal conductivity and an electronic device including the heat dissipation member are provided.

### BRIEF DESCRIPTION OF THE DRAWINGS

FIG. 1 is a schematic cross-sectional view illustrating one example of a configuration of a heat dissipation member according to an embodiment.

FIG. 2 is a cross-sectional view illustrating a heat dissipation member according to Example 1 in a lamination direction.

### DESCRIPTION OF EMBODIMENTS

Hereinafter, an embodiment of the present invention will be described using the drawings. In all of the drawings, the same components will be represented by the same reference numerals, and the description thereof will not be repeated. In addition, the diagrams are schematic diagrams, in which a dimensional ratio does not match the actual one.

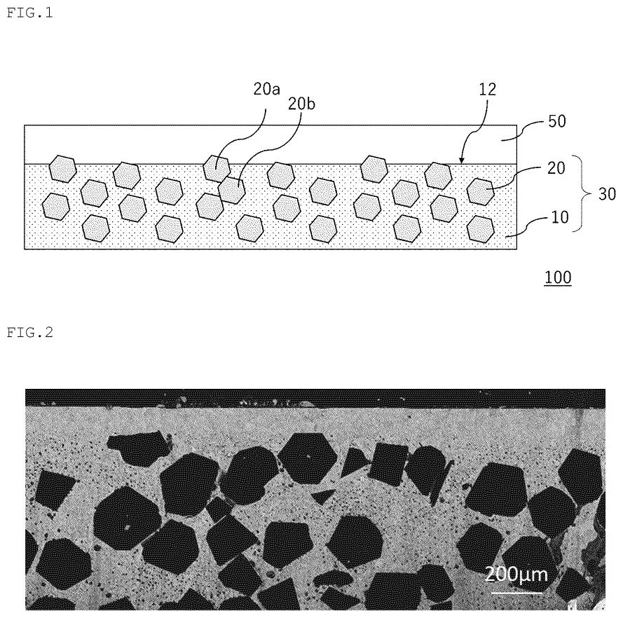

The summary of a heat dissipation member according to the present embodiment will be described using FIG. 1.

FIG. 1 is a schematic cross-sectional view illustrating one example of a configuration of the heat dissipation member according to the present embodiment.

A heat dissipation member 100 according to the present embodiment includes: a copper-diamond composite 30 where a plurality of diamond particles 20 are dispersed in a metal matrix 10 containing copper; and a metal film 50 that is joined to at least one face of the copper-diamond composite 30.

In at least one cross-section of the heat dissipation member 100 in a lamination direction, preferably in each of at least two cross-sections among cross-sections in the lamination direction, the plurality of diamond particles 20 are configured to include at least one first diamond particle (diamond particle 20a) in contact with both of the metal film 50 and the metal matrix 10.

In the heat dissipation member 100 according to the present embodiment, at least one first diamond particle (diamond particle 20a) in contact with both of the metal matrix 10, which is a metal phase of the copper-diamond composite 30 (hereinafter, also simply referred to as “composite”), and the metal film 50 is present. Due to the diamond particle 20a spanning both of the layers, thermal conductivity characteristics unique to diamond can be exhibited from the composite through the metal film 50. As a result, the thermal conductivity of the heat dissipation member 100 can be improved.

In addition, in the surface (joint interface 12) of the copper-diamond composite 30, the upper limit of a proportion of an exposed area of the diamond particles 20a obtained from (the exposed area of the diamond particles 20a/an area of the metal matrix 10)×100% is, for example, 50% or less, preferably 40% or less, and more preferably 30% or less.

On the other hand, the lower limit of the proportion of the exposed area of the diamond particles 20a is 18 or more, preferably 5% or more, and more preferably 10% or more.

By the limits being within the above-described ranges, the thermal conductivity of the heat dissipation member 100 can be improved.

In addition, in the heat dissipation member 100, the plurality of diamond particles 20 may be configured to include not only the first diamond particles (diamond particles 20a) that are in contact with both of the metal matrix 10 and the metal film 50 but also second diamond particles (diamond particles 20b) of which all faces are embedded in the metal matrix 10, and at least one (diamond particle 20a) of the first diamond particles and at least one (diamond particle 20b) of the second diamond particles may be configured to be in contact with each other. This connected structure may be configured by at least two or more, preferably three or more, and more preferably four or more diamond particles.

As a result, the thermal conductivity of the heat dissipation member 100 can be improved.

The above-described connected structure is found in at least one cross-section of the heat dissipation member 100 in the thickness direction.

In addition, according to further findings of the present inventors, it was found that the degree of smoothness of the surface of the copper-diamond composite or the degree of exposure of the diamond particles 20a can be appropriately controlled by appropriately adjusting the particle diameter or sphericity of the diamond particles, the grain size (grit number) of a grindstone used for grinding and polishing, and the like and using grinding means under mild conditions.

In addition, the detailed mechanism is not clear and is presumed to be that, by appropriately smoothing the surface of the copper-diamond composite using the grinding means under the mild conditions while suppressing fracture or separation of the diamond particles, the thickness of the metal film formed on the surface of the composite can be reduced, and thus the thermal conductivity of the entire heat dissipation member formed of the copper-diamond composite and the metal film can be improved. That is, when the surface of the copper-diamond composite is not smoothed, it is necessary to form the metal film with a large thickness to fill large unevenness present on the surface. However, when the thickness of the metal film on the surface of the composite increases, there is a concern that the entire thermal conductivity may decrease.

The lower limit of the thermal conductivity of the heat dissipation member 100 is preferably 600 W/m·K or higher, more preferably 630 W/m·K or higher, and still more preferably 650 W/m·K or higher. As a result, the heat dissipation characteristics of the heat dissipation member are improved.

On the other hand, the upper limit of the thermal conductivity of the heat dissipation member 100 is not particularly limited and is preferably 950 W/m·K or lower, more preferably 900 W/m·K or lower, and still more preferably 870 W/m·K or lower.

The configuration of the heat dissipation member according to the present embodiment will be described in detail.

The heat dissipation member 100 includes the copper-diamond composite 30 and the metal film 50.

### (Copper-Diamond Composite)

The copper-diamond composite 30 includes the metal matrix 10 containing copper and the plurality of diamond particles 20 present in the metal matrix 10.

The lower limit of the thermal conductivity of the copper-diamond composite 30 is preferably 600 W/m·K or higher, more preferably 630 W/m·K or higher, and still more preferably 650 W/m·K or higher. As a result, the heat dissipation characteristics of the heat dissipation member are enhanced.

On the other hand, the upper limit of the thermal conductivity of the copper-diamond composite 30 is not particularly limited and is preferably 950 W/m·K or lower, more preferably 900 W/m·K or lower, and still more preferably 870 W/m·K or lower.

The shape and size of the copper-diamond composite 30 can be appropriately set depending on uses.

Examples of the shape of the copper-diamond composite 30 include a flat shape, a block shape, and a rod shape.

The metal matrix 10 only needs to contain copper or may contain other high thermal conductivity metal other than copper. That is, the metal matrix 10 may be formed of a copper phase and/or a copper alloy phase.

As a main component in the metal matrix 10, copper is preferable from the viewpoint of thermal conductivity or costs.

The lower limit of the content of copper as the main component with respect to 100 mass& of the metal matrix 10 is preferably 50 mass % or more, more preferably 60 mass % or more, still more preferably 70 mass % or more, particularly preferably 80 masse or more, and most preferably 90 mass % or more. As a result, excellent thermal conductivity of the copper and the copper alloy can be used. In addition, in order to ensure brazing property and surface smoothness, the same copper as in the matrix can be used as a surface layer, and another surface coating layer does not need to be formed.

The upper limit of the content of copper as the main component with respect to 100 mass % of the metal matrix 10 is not particularly limited and may be 100 mass % or less or may be 99 mass % or less.

Examples of the other high thermal conductivity metal include silver, gold, and aluminum. These metals may be used alone or may be used in combination of two or more kinds. When copper and the other high thermal conductivity metal are used in combination, an alloy or a composite material formed of copper and the other high thermal conductivity metal can be used.

In the metal matrix 10, a metal or the like other than the high thermal conductivity metal is allowed within a range where the effect of the present invention does not deteriorate.

In addition, when the copper alloy is used as the metal matrix 10, examples of the copper alloy include CuAg, CuAl, CuSn, CuZr, and CrCu.

The metal matrix 10 is, for example, a sintered compact of metal powder containing copper (and optionally the other high thermal conductivity metal). In the present embodiment, the metal matrix 10 is formed of a sintered compact in which at least a part of the plurality of diamond particles 20 is embedded.

The diamond particles 20 are in a state where all the plurality of particles are embedded in the metal matrix 10. At least a part of one particle or a plurality of particles may be configured to be exposed on the joint interface 12 of the copper-diamond composite 30.

The diamond particles 20 includes at least any one of non-coated diamond particles not including a metal-containing coating layer on the surface or coated diamond particles including a metal-containing coating layer on the surface. From the viewpoint of improving the adhesiveness between diamond and metal particles or obtaining dispersibility, the coated diamond particles are more preferable.

The lower limit of a volume ratio of the diamond particles 20 in the copper-diamond composite 30 is preferably 10 volt or more, more preferably 20 vol % or more, and still more preferably 30 vol % or more. As a result, the thermal conductivity of the copper-diamond composite 30 is enhanced.

On the other hand, the upper limit of the volume ratio of the diamond particles 20 in the copper-diamond composite 30 is, for example, preferably 80 vol % or less, more preferably 70 vol % or less, and still more preferably 60 volt or less. As a result, in the copper-diamond composite 30, for example, attachment of the copper powder to the periphery of the diamond particles 20 deteriorates. As a result, the remaining of large pores can be suppressed, and a structure having excellent manufacturing stability can be realized.

When the coated diamond particles are used as the diamond particles 20, the metal-containing coating layer in the coated diamond particles may contain molybdenum, tungsten, chromium, zirconium, hafnium, vanadium, niobium, tantalum, and alloys thereof. These metals may be used alone or may be used in combination of two or more kinds. In addition, the metal-containing coating layer is configured to cover at least a part or all of the particle surfaces.

The sphericity or the particle diameter of the diamond particles 20 is measured in the following procedure.

The particle size distribution of the diamond particles 20 is measured using an image particle size distribution analyzer (for example, Morphologi 4, manufactured by Malvern Panalytical Ltd.). The particle size distribution includes a shape distribution or a particle diameter distribution.

A volume particle size distribution of sphericity or a volume particle size distribution of particle diameter is generated from the obtained particle size distribution.

In the volume particle size distribution of sphericity of the diamond particles 20, a sphericity corresponding to a predetermined cumulative value or a particle diameter corresponding to a predetermined cumulative value is obtained.

Here, the sphericity and the particle diameter are defined as follows.

Sphericity: a ratio between the circumferential length of a circumference having the same area as a projected object and the circumferential length of the object

Particle diameter: the maximum length between two points on the contour of a particle image

The lower limit of a sphericity S₅₀ corresponding to a cumulative value of 50% in the diamond particles 20 that is measured in the above-described procedure is, for example, 0.75 or more, preferably 0.80 or more, more preferably 0.85 or more, and still more preferably 0.9 or more. As a result, the filling density of the diamond particles 20 is enhanced, and the thermal conductivity of the composite is enhanced.

On the other hand, the upper limit of the sphericity S₅₀ is not particularly limited and may be, for example, 1.0 or less or 0.99 or less.

The upper limit of a particle diameter D₅₀ corresponding to a cumulative value of 50% in the diamond particles 20 that is measured in the above-described procedure is, for example, 300 μm or less, preferably 270 μm or less, more preferably 250 μm or less, still more preferably 220 μm or less, particularly preferably 200 μm or less, and most preferably 180 μm or less. As a result, the filling density of the diamond particles 20 is enhanced, and the thermal conductivity of the composite is enhanced.

The lower limit of the above-described particle diameter D₅₀ is not particularly limited and may be, for example, 5 μm or more.

The upper limit of a flatness of the copper-diamond composite 30 calculated according to JIS B 0621:1984 is, for example, 40 μm or less, preferably 39 μm or less, and more preferably 38 μm or less. As a result, the adhesiveness between the composite and the metal film can be improved.

On the other hand, the above-described lower limit of the flatness is not particularly limited and may be 1 μm or more.

On the diamond particle surfaces exposed from the surface (joint interface 12) of the copper-diamond composite 30, the upper limit of a ten-point average height calculated according to JIS B 0601:2013 is, for example, 5 μm or less, preferably 4 μm or less, and more preferably 3 μm or less. As a result, the adhesiveness between the composite and the metal film can be improved.

On the other hand, the above-described lower limit of the ten-point average height of the diamond particle surfaces is not particularly limited and may be 0.1 μm or more.

### (Metal Film)

The metal film 50 only needs to be formed on at least one face of the copper-diamond composite 30 and may be formed on each of both faces of the flat copper-diamond composite 30.

The metal film 50 may contain one or two or more selected from the group consisting of copper, silver, gold, aluminum, nickel, zinc, tin, and, magnesium. It is preferable that the metal film 50 includes the same metal as the metal as the main component in the metal matrix 10, and it is more preferable that the metal film 50 includes at least copper or a copper alloy.

The content of copper as the main component with respect to 100 mass& of the metal film 50 is preferably 50 mass& or more, more preferably 60 mass % or more, still more preferably 70 mass& or more, particularly preferably 80 mass % or more, and most preferably 90 mass % or more.

The upper limit of the content of copper as the main component with respect to 100 mass % of the metal film 50 is not particularly limited and may be 100 mass % or less or may be 99 mass % or less.

The upper limit of the thickness of the metal film 50 is preferably 150 μm or less, more preferably 120 μm or less, and still more preferably 100 μm or less. As a result, the thermal conductivity of the heat dissipation member is enhanced.

On the other hand, the lower limit of the thickness of the metal film 50 is preferably 10 μm or more, more preferably 15 μm or more, and still more preferably 20 μm or more. As a result, the adhesion strength with the composite or the durability of the metal film 50 itself is enhanced.

The metal film 50 is obtained, for example, using a sputtering method or a plating method.

An average crystal grain diameter of the metal in the metal film 50 is preferably 5 nm or more and 50 nm or less, more preferably 10 nm or more and 40 nm or less, and still more preferably 20 nm or more and 30 nm or less. The average crystal grain diameter is measured using a transmission electron microscope (TEM).

An electronic device according to the present embodiment includes the above-described heat dissipation member and an electronic component that is provided over the heat dissipation member.

Examples of the electronic component include a semiconductor element. Specific examples of the semiconductor element include a power semiconductor, an image display element, a microprocessor unit, and a laser diode.

The heat dissipation member is used as a heat sink, a heat spreader, or the like. The heat sink dissipates heat generated during an operation of the semiconductor element to an external space, and the heat spreader spreads heat generated from the semiconductor element to other members.

The electronic component may be provided in the heat dissipation member directly or indirectly through a ceramic substrate or the like.

An example of a method of manufacturing the heat dissipation member according to the present embodiment will be described.

An example of the method of manufacturing the heat dissipation member includes a raw material mixing step, a sintering step, a smoothing step, and a film forming step.

In the raw material mixing step, metal powder including copper such as copper powder and diamond particles are mixed to obtain a mixture.

To the mixing of the raw material powders, various methods such as a dry process or a wet process can be applied, and a dry mixing method may also be used.

In the firing step, the mixture of the metal powder and the diamond particles is fired to obtain a composite sintered compact of copper and the diamond particles.

The firing temperature can be appropriately selected depending on metal species in the metal powder. The firing temperature of the copper powder is preferably 800° C. or higher and 1100° C. or lower and more preferably 850° C. or higher and 1000° C. or lower. By adjusting the firing temperature to be 800° C. or higher, the copper-diamond composite is densified to obtain a desired thermal conductivity. By adjusting the firing temperature to be 1100° C. or lower, deterioration of the interface of the diamond particles caused by graphitization can be suppressed, and a decrease in the thermal conductivity of diamond itself can be prevented.

The firing time is not particularly limited and is preferably 5 minutes or longer and 3 hours or shorter and more preferably 10 minutes or longer and 2 hours or shorter. By adjusting the firing time to be 5 minutes or longer, the copper-diamond composite is densified to obtain a desired thermal conductivity. By adjusting the firing time to be 3 hours or shorter, the formation of a carbide between diamond in the coated diamond particles and the metal with which the surfaces are coated or an increase in film thickness can be suppressed, and a decrease in thermal conductivity caused by phonon scattering or the occurrence of cracks caused by a difference in linear expansion coefficient can be suppressed. In addition, the productivity of the composite is improved.

In the firing step, a pressureless sintering method or a pressure sintering method may be used, and a pressure sintering method is preferable to obtain a dense composite.

Examples of the pressure sintering method include hot press sintering, spark plasma sintering (SPS), and hot isotropic pressure sintering (HIP). In hot press sintering or SPS sintering, the pressure is preferably 10 MPa or higher and more preferably 30 MPa or higher. On the other hand, in hot press sintering or SPS sintering, the pressure is preferably 100 MPa or lower. By adjusting the pressure to be 10 MPa or higher, the copper-diamond composite is densified to obtain a desired thermal conductivity. By adjusting the pressure to be 100 MPa or lower, the fracture of diamond can be prevented, an increase in diamond interface or a decrease in adhesiveness between a diamond fracture surface and metal can be prevented, and a decrease in the thermal conductivity of diamond itself can be prevented.

In the smoothing step, at least a part of the surface of the composite sintered compact is ground and polished to obtain the copper-diamond composite.

In the film forming step, the metal film is formed on at least a part of the smoothed surface of the copper-diamond composite.

As a method of forming the metal film, a general method such as a sputtering method, a plating method, or a pressure co-firing method using copper foil may be adopted. However, a sputtering method may be used to reduce the film thickness.

In addition, at least a part of the surface of the metal film may be ground and polished. As a result, the surface smoothness of the metal film after the film forming step can be improved.

In addition, an annealing step may be added and performed between the firing step and the smoothing step.

In addition, a step of performing processing such as shaping or perforating on the copper-diamond composite may be performed before the film forming step.

Hereinbefore, the embodiment of the present invention has been described. However, the embodiment is merely an example of the present invention, and various configurations other than the above-described configurations can be adopted. In addition, the present invention is not limited to the above-described embodiments, and modifications, improvements, and the like within a range where the object of the present invention can be achieved are included in the present invention.

### EXAMPLES

Hereinafter, the present invention will be described in detail with reference to Examples. However, the present invention is not limited to the description of these Examples.

### <Preparation of Composite and Heat Dissipation Member>

### Example 1

Copper powder and diamond particles (coated with Mo) were weighed at 50 vol %:50 vol %, and the weighed powders were uniformly mixed using a V-shape mixer to obtain a mixture (raw material mixing step).

Next, using a SPS firing device, the obtained mixture was filled in a mold and was heated and sintered at 900° C. for 1 hour under a pressure condition of 30 MPa. As a result, a disk-shaped composite sintered compact where a plurality of diamond particles were dispersed in the copper matrix was obtained (sintering step).

A particle size distribution (shape distribution/particle diameter distribution) of the diamond particles as a raw material was measured using an image particle size distribution analyzer (for example, Morphologi 4, manufactured by Malvern Panalytical Ltd.).

A sphericity S₅₀ corresponding to a cumulative value of 50% in the volume particle size distribution of sphericity of the diamond particles and a particle diameter D₅₀ corresponding to a cumulative value of 50% in the volume particle size distribution of particle diameter of the diamond particles were obtained. Each of these values was an average value of two measured values.

The sphericity and the particle diameter were defined as follows.

Sphericity: a ratio between the circumferential length of a circumference having the same area as a projected object and the circumferential length of the object

Particle diameter: the maximum length between two points on the contour of a particle image As a result, in the diamond particles used, the sphericity S₅₀ was 0.9, and the particle diameter D₅₀ was 200 μm.

Both surfaces of the obtained composite sintered compact were ground and polished to be smoothed using a #400 grindstone. As a result, a copper-diamond composite (ground composite sintered compact) having an outer diameter of 30 mmφ and a thickness of 3 mm was obtained (smoothing step).

The content of the diamond particles in the copper-diamond composite was 50.8 vol %.

A flatness of the copper-diamond composite on one surface (surface region ranging from the copper matrix to the diamond particles) among the smoothed surfaces was observed and measured using a digital microscope (VHX-8000, manufactured by Keyence Corporation). The flatness calculated according to JIS B 0621:1984 was 30.1 μm.

In addition, a ten-point average height of the diamond particle surfaces (ten-point average height Rz of the diamond surfaces) exposed on the surface of the copper-diamond composite was 1.5 μm when calculated according to JIS B 0601:2013.

In addition, in the surface of the copper-diamond composite, the area of the copper matrix and the exposed area of the diamond particles were measured. The proportion (%) of the exposed area of the diamond particles was obtained from the expression: the exposed area of the diamond particles/the area of the copper matrix (metal matrix)×100.

In addition, when the thermal conductivity of the copper-diamond composite was measured using a laser flash method, the result was 753 W/m·K. The measurement using the laser flash method was performed at room temperature after coating the sample surface with carbon.

Next, a Cu film having a thickness of 30 μm was formed using a sputtering method on each of both faces of the copper-diamond composite. As a result, a heat dissipation member formed of the Cu film/the copper-diamond composite/the Cu film was obtained (film forming step).

When the thermal conductivity of the heat dissipation member was measured using a laser flash method, the result was 748 W/m·K.

The average crystal grain diameter of the Cu film in the heat dissipation member was 26 nm. In a method of measuring the crystal grain diameter, the crystal grain diameter was calculated from the number of crystal grains in a range of 1 μm² of a structure obtained using a transmission electron microscope.

FIG. 2 is a cross-sectional SEM image of the heat dissipation member according to Example 1 in a thickness direction (lamination direction of the composite and the Cu film).

In FIG. 2, the presence of a plurality of the first diamond particles in contact with the copper phase (metal matrix) and the Cu film (metal film) in the copper-diamond composite was found. In addition, a connected structure where the second diamond particle of which all the circumferences were embedded in the copper phase in the composite and the first diamond a part of which was exposed from the composite were in contact with each other was found.

### Examples 2 to 6 and Comparative Examples 1 and 2

Composites and heat dissipation members were obtained using the same method as that of Example 1, except that the particle diameter and the sphericity of the diamond particles were changed as shown in Table 1 and the conditions such as grinding and polishing conditions were changed as shown in Notes.

The same evaluation as that of Example 1 was performed on the obtained composites and the obtained heat dissipation members.

In each of the two cross-sectional SEM images of the heat dissipation members according to Examples 2 to 6, the presence of the plurality of first diamond particles and the presence of the second diamond particles and the connected structure were found.

TABLE 1

| | | | | | | Cu Film/Copper-Diamond | | |
|---|---|---|---|---|---|---|---|---|
| | Diamond Particles | | Copper-Diamond Composite | | | Composite/Cu Film | | |
| | Particle | | | Proportion of Exposed | Thermal | Cu Film | Thermal | |
| | Diameter | Sphericity | Flatness | Area of Diamond | Conductivity | Thickness | Conductivity | |
| | D₅₀ (μm) | S₅₀ | (μm) | Particles (%) | (W/m · K) | (μm) | (W/m · K) | Notes |
| Example 1 | 200 | 0.9 | 30.1 | 18.7 | 753 | 30 | 748 | #400 Grinding and |
| | | | | | | | | Polishing |
| Example 2 | 200 | 0.8 | 36.5 | 25.9 | 693 | 30 | 685 | #400 Grinding and |
| | | | | | | | | Polishing, Diamond |
| | | | | | | | | Sphericity |
| Example 3 | 200 | 0.9 | 32.9 | 19.3 | 758 | 100 | 637 | #400 Grinding and |
| Example 4 | 200 | 0.9 | 30.5 | 22.8 | 751 | 20 | 749 | Polishing, Cu |
| | | | | | | | | Thickness |
| Example 5 | 100 | 0.9 | 27.3 | 15.5 | 755 | 30 | 753 | #400 Grinding and |
| Example 6 | 50 | 0.9 | 25.4 | 14.2 | 707 | 30 | 701 | Polishing, Diamond |
| | | | | | | | | Particle Diameter |
| Comparative | 200 | 0.9 | 247 | 51.0 | 749 | 30 | 582 | No Grinding |
| Example 1 | | | | | | | | |
| Comparative | 200 | 0.7 | 41.5 | 56.9 | 628 | 30 | 593 | #400 Grinding and |
| Example 2 | | | | | | | | Polishing, Diamond |
| | | | | | | | | Sphericity |

Table 1 shows the results that the heat dissipation members according to Examples 1 to 6 can realize a higher thermal conductivity than Comparative Examples 1 and 2.

The present application claims priority based on Japanese Patent Application No. 2021-129884, filed on Aug. 6, 2021, the entire content of which is incorporated herein by reference.

### REFERENCE SIGNS LIST

10: metal matrix
12: joint interface
20,20a,20b: diamond particle
30: copper-diamond composite
50: metal film
100: heat dissipation member

1. A heat dissipation member comprising:
a copper-diamond composite where a plurality of diamond particles are dispersed in a metal matrix containing copper; and
a metal film that is joined to at least one face of the copper-diamond composite, wherein
in at least one cross-section of the heat dissipation member in a lamination direction, at least one of the plurality of diamond particles is configured to be in contact with both of the metal film and the metal matrix, and
in a surface of the copper-diamond composite, a proportion of an exposed area of the diamond particles obtained from (the exposed area of the diamond particles/an area of the metal matrix)×100% is 1% or more and 50% or less.

2. The heat dissipation member according to claim 1, wherein
the plurality of diamond particles include not only first diamond particles that are in contact with both of the metal film and the metal matrix but also second diamond particles of which all faces are embedded in the metal matrix, and
at least one of the first diamond particles and at least one of the second diamond particles are configured to be in contact with each other.

3. The heat dissipation member according to claim 1, wherein
a thermal conductivity of the copper-diamond composite is 600 W/m·K or higher.

4. The heat dissipation member according to claim 1, wherein
when a particle size distribution of the diamond particles is measured using an image particle size distribution analyzer, a sphericity S₅₀ corresponding to a cumulative value of 50% in a volume particle size distribution of sphericity of the diamond particles is 0.75 or more.

5. The heat dissipation member according to claim 1, wherein
when a particle size distribution of the diamond particles is measured using an image particle size distribution analyzer, a particle diameter D₅₀ corresponding to a cumulative value of 50% in a volume particle size distribution of particle diameter of the diamond particles is 300 μm or less.

6. An electronic device comprising:
the heat dissipation member according to claim 1; and
an electronic component that is provided over the heat dissipation member.
